(19) United States
(12) Patent Application Publication
(10) Pub. No.: US 2024/0332460 A1
(43) Pub. Date: Oct. 3, 2024

(54) DISPLAY SUBSTRATE, METHOD FOR MANUFACTURING DISPLAY SUBSTRATE, AND DISPLAY DEVICE

(71) Applicant: BOE TECHNOLOGY GROUP CO., LTD., Beijing (CN)

(72) Inventors: Jiaxiang Zhang, Beijing (CN); Ke Wang, Beijing (CN); Zhanfeng Cao, Beijing (CN)

(21) Appl. No.: 18/246,452

(22) PCT Filed: Jun. 30, 2022
(86) PCT No.: PCT/CN2022/102983

§ 371 Date: Mar. 23, 2023

(51) Int. Cl. H01L 33/44; H01L 25/075; H01L 33/38; H01L 33/62

(52) U.S. Cl. CPC H01L 33/44; H01L 25/0753; H01L 33/382; H01L 33/62; H01L 2933/0025

(57) ABSTRACT

A display substrate, a method for manufacturing the display substrate, and a display device are provided. The display substrate includes: a base substrate; a metal layer on the base substrate, including a copper layer having a first thickness; an anti-oxidation layer on a side of the metal layer away from the base substrate, having a second thickness; and a light emitting diode on a side of the anti-oxidation layer away from the base substrate, including at least one electrode electrically connected to the metal layer, where the first thickness of the metal layer is larger than the second thickness of the anti-oxidation layer.

### CROSS-REFERENCE TO RELATED APPLICATION

This application is a Section 371 National Stage Application of International Application No. PCT/CN2022/102983, filed Jun. 30, 2022, entitled “DISPLAY SUBSTRATE, METHOD FOR MANUFACTURING DISPLAY SUBSTRATE, AND DISPLAY DEVICE”, incorporated herein by reference in its entirety.

### TECHNICAL FIELD

The present disclosure relates to a field of display technology, and in particular to a display substrate, a method for manufacturing the display substrate, and a display device.

### BACKGROUND

The Light Emitting Diode (LED) technology has been developed for nearly 30 years, and its application scope is continuously expanding. For example, it can be applied to the display field, used as a backlight source of a display device or as an LED display screen. With the development of technology, Mini Light Emitting Diode (Mini LED) display technology and Micro Light Emitting Diode (Micro LED) display technology have gradually become a hot spot of display devices. LED has the advantages of self-illumination, wide viewing angle, fast response, simple structure and long service life, and a large-size display may be realized by splicing Mini LED/Micro LED display screens. As a result, they have a good market prospect. So far, structures and manufacturing techniques of Mini LED/Micro LED display devices are one of the important topics that researchers are concerned about.

The above information disclosed in this section is only for the understanding of the background of the inventive concept of the present disclosure and therefore it may contain information that does not constitute the prior art.

### SUMMARY

In order to solve at least one of the above problems, according to the embodiments of the present disclosure, there is provided a display substrate and a method for manufacturing the same, and a display device.

According to an aspect, there is provided a display substrate, including: a base substrate; a metal layer on the base substrate, including a copper layer having a first thickness; an anti-oxidation layer on a side of the metal layer away from the base substrate, having a second thickness; and a light emitting diode on a side of the anti-oxidation layer away from the base substrate, including at least one electrode, where the at least one electrode of the light emitting diode is electrically connected to the metal layer. The first thickness of the metal layer is larger than the second thickness of the anti-oxidation layer.

According to some exemplary embodiments, the anti-oxidation layer includes a nickel-containing alloy.

According to some exemplary embodiments, the base substrate includes a display region and a mark region, and the display substrate includes a first accompanying plating region in the mark region and a second accompanying plating region in the display region. Each of the first accompanying plating region and the second accompanying plating region includes a copper layer, and a ratio of an area of the first accompanying plating region to an area of the mark region is larger than a ratio of an area of the second accompanying plating region to an area of the display region.

According to some exemplary embodiments, the display substrate further includes a mark in the mark region and a clearance region in the mark region. The first accompanying plating region surrounds the mark, and the clearance region is between the mark and the first accompanying plating region and surrounds the mark.

According to some exemplary embodiments, an orthographic projection of the first accompanying plating region on the base substrate is a loop-shaped region surrounding the mark.

According to some exemplary embodiments, the anti-oxidation layer covers the metal layer, and the at least one electrode of the light emitting diode is electrically connected to the metal layer through the anti-oxidation layer.

According to some exemplary embodiments, the display substrate further includes: a passivation layer on the anti-oxidation layer away from the base substrate and a first via hole in the passivation layer. The first via hole exposes at least a part of the anti-oxidation layer, and the at least one electrode of the light emitting diode is electrically connected to the metal layer through the first via hole.

According to some exemplary embodiments, the anti-oxidation layer covers the metal layer.

According to some exemplary embodiments, the display substrate further includes: a passivation layer on the anti-oxidation layer away from the base substrate and a third via hole in the passivation layer. The third via hole is located at a pad position of the display region and exposes at least a part of the metal layer, and the at least one electrode of the light emitting diode is electrically connected to the metal layer through the third via hole.

According to some exemplary embodiments, the display substrate further includes a fourth via hole in the passivation layer. The fourth via hole is located at a bonding position and exposes at least a part of the anti-oxidation layer, and the at least one electrode of the light emitting diode is electrically connected to the metal layer through the exposed part of the anti-oxidation layer.

According to some exemplary embodiments, the anti-oxidation layer includes an opening exposing at least a part of the metal layer, and an orthographic projection of the third via hole on the base substrate is located within an orthographic projection of the opening on the base substrate.

According to another aspect, there is provided a method for manufacturing a display substrate, including:
depositing a copper seed layer on a base substrate;
forming a photoresist layer on a side of the copper seed layer away from the base substrate;
patterning the photoresist layer by using a patterning process to form a photoresist pattern;
forming a copper layer on a part of the copper seed layer not covered by the photoresist pattern by using an electroplating process;
removing the photoresist pattern and a part of the copper seed layer not covered by the metal layer to form a metal layer including copper;
forming an anti-oxidation layer on a side of the metal layer away from the base substrate; and
mounting a light emitting diode on a side of the anti-oxidation layer away from the base substrate, where the light emitting diode includes at least one electrode electrically connected to the metal layer,
where a first thickness of the metal layer is larger than a second thickness of the anti-oxidation layer.

According to some exemplary embodiments, the base substrate includes a display region and a mark region, and
the forming a copper layer on a part of the copper seed layer not covered by the photoresist pattern by an electroplating process includes:
forming a first accompanying plating region in the mark region; and
forming a second accompanying plating region in the display region,
where each of the first accompanying plating region and the second accompanying plating region includes a part of the copper layer; and
where a ratio of an area of the first accompanying plating region to an area of the mark region is larger than a ratio of an area of the second accompanying plating region to an area of the display region.

According to some exemplary embodiments, the method further includes forming a mark by an electroplating process in a region surrounded by the first accompanying plating region.

According to some exemplary embodiments, the forming an anti-oxidation layer on a side of the metal layer away from the base substrate includes:
forming a passivation layer on the side of the metal layer away from the base substrate;
forming a first via hole in the passivation layer, where the first via exposes at least a part of the metal layer; and
forming the anti-oxidation layer in the first via hole,
where the anti-oxidation layer includes an organic solderability preservative film.

According to some exemplary embodiments, the forming an anti-oxidation layer on a side of the metal layer away from the base substrate includes: forming a nickel-containing alloy layer covering the metal layer on the side of the metal layer away from the base substrate.

According to some exemplary embodiments, the forming an anti-oxidation layer on a side of the metal layer away from the base substrate includes:
forming a nickel-containing alloy layer covering the metal layer on the side of the metal layer away from the base substrate;
forming a passivation layer on a side of the nickel-containing alloy layer away from the base substrate; and
forming a second via hole in the passivation layer, where the second via hole exposes at least a part of the nickel-containing alloy layer.

According to some exemplary embodiments, the forming an anti-oxidation layer on a side of the metal layer away from the base substrate includes:
forming a nickel-containing alloy layer covering the metal layer on the side of the metal layer away from the base substrate;
forming an opening in the nickel-containing alloy layer at a pad position of the display region, where the opening exposes at least a part of the metal layer;
forming a passivation layer on a side of the nickel-containing alloy layer away from the base substrate; and
forming a third via hole in the passivation layer at the pad position of the display region, where the third via hole exposes at least a part of the metal layer, where an orthographic projection of the third via hole on the base substrate is located within an orthographic projection of the opening on the base substrate.

According to some exemplary embodiments, the forming an anti-oxidation layer on a side of the metal layer away from the base substrate further includes: forming a fourth via hole in the passivation layer at a bonding position, where the fourth via hole exposes at least a part of the nickel-containing alloy layer.

According to yet another aspect, there is provided a display device, including the display substrate as described above.

### BRIEF DESCRIPTION OF THE DRAWINGS

Other objectives and advantages of the present disclosure will be apparent from the following description of the present disclosure with reference to the accompanying drawings, and which may help a comprehensive understanding of the present disclosure.

FIG. 1 shows a schematic top view of a display substrate according to some exemplary embodiments of the present disclosure, where for illustration, an unfolded state of the display substrate and another substrate bonded thereto is shown.

FIG. 2 shows a sectional view of a display substrate taken along line AA′ in FIG. 1 according to some exemplary embodiments of the present disclosure.

FIG. 3 shows a flowchart of a method for forming a copper layer by using the subtractive process in a related technology.

FIG. 4 shows a flowchart of a method for manufacturing a display substrate according to some exemplary embodiments of the present disclosure.

FIG. 5A shows a partial schematic top view of a display substrate according to some exemplary embodiments of the present disclosure, where a display region and a mark region are schematically shown.

FIG. 5B shows a partially enlarged diagram of the marked region shown in FIG. 5A.

FIG. 5C shows a partially enlarged diagram of the display region shown in FIG. 5A.

FIG. 6A shows a schematic diagram of a mark formed by a method for manufacturing a display substrate according to some exemplary embodiments of the present disclosure.

FIG. 6B shows a schematic diagram of a mark formed by a method for manufacturing a display substrate in a related technology.

FIG. 7 shows a partial sectional view of a display substrate according to some exemplary embodiments of the present disclosure, where a positional relationship between a metal layer and an anti-oxidation layer is schematically shown.

FIG. 8A and FIG. 8B respectively show electron microscope images of regions I and II in FIG. 7.

FIG. 9A shows a partial sectional view of a display substrate according to some other exemplary embodiments of the present disclosure, where a positional relationship between a metal layer and an anti-oxidation layer is schematically shown.

FIG. 9B shows an electron microscopic image of region III in FIG. 9A.

FIG. 10A and FIG. 10B respectively show a partial sectional view and a partial top view of a display substrate according to yet some other exemplary embodiments of the present disclosure, where a positional relationship between a metal layer and an anti-oxidation layer is schematically shown.

FIG. 11 shows a partial sectional view of a display substrate according to some other exemplary embodiments of the present disclosure, where a positional relationship between a metal layer and an anti-oxidation layer is schematically shown.

FIG. 12A and FIG. 12B respectively show partial sectional views of a display substrate at a first position and a second position according to some other exemplary embodiments of the present disclosure, where a positional relationship between a metal layer and an anti-oxidation layer is schematically shown.

FIG. 13 shows a schematic diagram of an arrangement of light emitting units of the display substrate shown in FIG. 1.

FIG. 14 shows a schematic diagram of a light emitting unit in the display substrate shown in FIG. 13.

It should be noted that for clarity, in the drawings used to describe the embodiments of the present disclosure, sizes of layers, structures or regions may be enlarged or reduced, i.e., the drawings are not drawn according to the actual scale.

### DETAILED DESCRIPTION OF EMBODIMENTS

In the following description, for explanation, numerous specific details are set forth in order to provide a thorough understanding of various exemplary embodiments. However, it is obvious that the various exemplary embodiments may be implemented without these specific details, or with one or more equivalent arrangements. In other situations, well-known structures and devices are shown in the form of block diagram in order to avoid unnecessarily obscuring the various exemplary embodiments. In addition, the various exemplary embodiments may be different, but are not necessarily exclusive. For example, the specific shape, configuration, and characteristics of one exemplary embodiment may be used or implemented in another exemplary embodiment without departing from the inventive concept.

In the drawings, the sizes and relative sizes of elements may be enlarged for clarity and/or the description. As such, the sizes and relative sizes of various elements are not necessarily limited to those shown in the drawings. When exemplary embodiments may be implemented differently, a specific process sequence may be performed differently from the sequence described. For example, two consecutively described processes may be performed substantially simultaneously or in a sequence reverse to that described. In addition, the same reference sign denotes the same element.

When an element is described as being “on”, “connected to”, or “coupled to” another element, the element may be directly on, directly connected to, or directly coupled to another element, or an intermediate element may be present. However, when an element is described as being “directly on”, “directly connected to”, or “directly coupled to” another element, no intermediate element is present. Other terms and/or expressions used to describe the relationship between elements should be interpreted in a similar manner, for example, “between” versus “directly between”, “adjacent” versus “directly adjacent”, “on” versus “directly on”, etc. Additionally, the term “connection” may refer to a physical connection, an electrical connection, a communication connection, and/or a fluid connection. Additionally, the axis X, the axis Y, and the axis Z are not limited to the three axes of a rectangular coordinate system, and they may be interpreted in a wider sense. For example, the axis X, the axis Y, and the axis Z may be perpendicular to one another, or they may represent different directions that are not perpendicular to one another. For the objective of the present disclosure, the expressions “at least one of X, Y, and Z” and “at least one selected from a group consisting of X, Y, and Z” may be interpreted as “only X, only Y, only Z” or “any combination of two or more of X, Y, and Z, such as XYZ, XY, YZ and XZ”. As used herein, the term “and/or” includes any and all combinations of one or more of the associated items listed.

It will be understood that the terms first, second, etc. may be used herein to describe various elements, but these elements should not be limited by these terms. These terms are only used to distinguish one element from another. For example, a first element may be termed a second element, and, similarly, a second element may be termed a first element, without departing from the scope of the exemplary embodiments.

In the present disclosure, an inorganic light emitting diode refers to a light emitting element made of an inorganic material, where an LED refers to an inorganic light emitting element which is different from an OLED. Specifically, an inorganic light emitting element may include a Mini Light Emitting Diode (Mini LED) and a Micro Light Emitting Diode (Micro LED). A micro light emitting diode (i.e., Micro LED) refers to an ultra-small light emitting diode with a grain size below 100 microns, and a mini light emitting diode (i.e., Mini LED) refers to a small LED with a grain size between a grain size of a Micro LED and a grain size of a traditional LED. For example, the grain size of a Mini LED may be between 100 microns and 300 microns, and the grain size of a Micro LED may be between 10 microns and 100 microns.

Wire Bonding is a process to tightly weld a metal bonding wire to a substrate pad using heat, pressure or ultrasonic energy. For example, wire bonding may be used in an IC encapsulation process to connect a semiconductor chip soldering zone with an I/O bonding wire of a microelectronic encapsulation or a metal wire soldering zone on a substrate through metal filaments. The principle of wire bonding is to destroy the oxide layer and dirt on a surface to be soldered by means of heating, pressurizing or ultrasonic waves and produce plastic deformation, so that a metal bonding wire is in close contact with the surface to be soldered. As such, a range of gravitational force between atoms is reached, and atomic diffusion among interfaces is caused, so as to form a solder joint.

OSP is the abbreviation of organic solderability preservatives, which may be referred to as an organic solderability preservative film, also known as a copper protection agent. OSP is an organic surface film grown chemically on a clean bare copper surface. This film has oxidation resistance, thermal shock resistance, and moisture resistance, and is used to protect the copper surface from rusting (oxidation, vulcanization, etc.) in a normal environment. Under a subsequent soldering high temperature, this protective film may be easily and quickly removed by a solder flux, so that an exposed clean copper surface may be immediately joined with molten soldering tin to form a solid solder joint in a very short time.

According to some exemplary embodiments of the present disclosure, there is provided a display substrate, a method for manufacturing the display substrate, and a display device including the display substrate. For example, according to some embodiments of the present disclosure, there is provided a display substrate, including: a base substrate; a metal layer on the base substrate, including a copper layer having a first thickness; an anti-oxidation layer on a side of the metal layer away from the base substrate, having a second thickness; and a light emitting diode on a side of the anti-oxidation layer away from the base substrate, including at least one electrode, where the at least one electrode of the light emitting diode is electrically connected to the metal layer. The first thickness of the metal layer is larger than the second thickness of the anti-oxidation layer. In the embodiments of the present disclosure, a display substrate with a highly thick copper layer may be achieved, and the copper layer may be prevented from being oxidized by using a film layer design of an anti-oxidation layer.

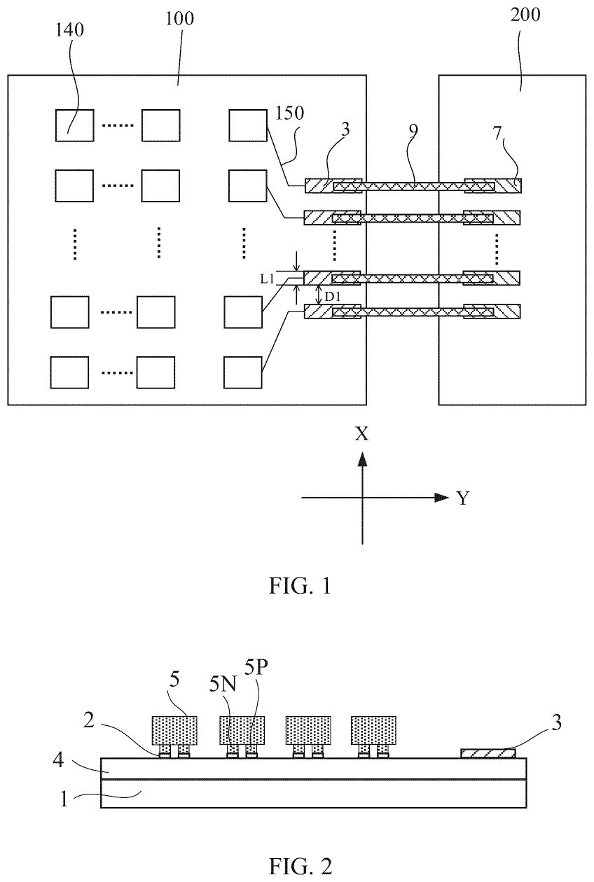

FIG. 1 shows a schematic top view of a display substrate according to some exemplary embodiments of the present disclosure. It should be noted that, for illustration, FIG. 1 shows an unfolded state of the display substrate and another substrate bonded thereto. FIG. 2 shows a sectional view of a display substrate taken along line AA′ in FIG. 1 according to some exemplary embodiments of the present disclosure.

Referring to FIG. 1 and FIG. 2, a display substrate 100 may include a base substrate 1 and a plurality of first electrodes 2 and a plurality of first conductive pads 3 that are arranged on the base substrate 1. The plurality of first conductive pads 3 are at an edge of the display substrate 100. For example, the plurality of first conductive pads 3 are in a fan-out region of the display substrate 100, and are used to electrically connect signal lines (for example, some of the signal lines 150 schematically shown in FIG. 1) in the display substrate 100 to an external driver circuit.

For example, a material of the base substrate 1 may include but not limited to glass, quartz, plastic, silicon, polyimide and the like. The first electrode 2 and the first conductive pad 3 may have columnar structures. The material of the first electrodes 2 and the first conductive pads 3 may include a conductive material, such as a metal material. Specifically, the material of the first electrodes 2 and the first conductive pads 3 may be at least one or a combination of at least two selected from gold, silver, copper, aluminum, molybdenum, a gold alloy, a silver alloy, a copper alloy, an aluminum alloy, a molybdenum alloy and the like, which is not limited in the embodiments of the present disclosure.

For example, the display substrate 100 may further include a driver circuit 4 electrically connected to the plurality of first electrodes 2, and the driver circuit 4 is arranged on the base substrate 1. The driver circuit 4 may be used to provide an electrical signal to light emitting diode chips 5 on the plurality of first electrodes 2, so as to control the brightness of the light emitting diode chips 5. For example, in some examples, the driver circuit 4 may be a structure such as a plurality of pixel driver circuits which are connected to the light emitting diode chips in a one-to-one correspondence, or a plurality of micro integrated circuit chips which are connected to the light emitting diode chips in a one-to-one correspondence, and may control the respective light emitting diode chips to achieve gray scales with different brightness. It should be noted that the specific circuit structure of the driver circuit 4 on the display substrate 100 may be designed as desired, which is not limited in the embodiments of the present disclosure.

In a specific manufacturing method, a plurality of light emitting diodes 5 may be transferred and bonded to the display substrate 100.

Referring to FIG. 1 and FIG. 2, the light emitting diode 5 includes an N electrode 5N and a P electrode 5P. Each of the N electrode and the P electrode of the light emitting diode 5 is connected to a respective first electrode 2, and the surfaces of the plurality of first conductive pads 3 are exposed.

Referring to FIG. 1, a plurality of light emitting diodes are arranged in an array along a first direction X and a second direction Y. For example, the first direction X is a row direction and the second direction Y is a column direction. However, the embodiments of the present disclosure are not limited thereto. The first direction and the second direction may be any directions, as long as the first direction and the second direction intersect. In addition, the plurality of light emitting diodes are not limited to be arranged along a straight line, and they may also be arranged along a curved line or a ring, or may be arranged in any manner, which may be determined as desired and is not limited in the embodiments of the present disclosure.

The plurality of first conductive pads 3 are arranged at the edge of the display substrate 100 along the first direction X, that is, the plurality of first conductive pads 3 form a row of first conductive pads. For example, the plurality of first conductive pads 3 are arranged at equal intervals along the first direction X.

For example, the light emitting diode may include a micro light emitting diode (Micro-LED) or a mini light emitting diode (Mini-LED).

For example, a second substrate 200 may be a circuit board, such as a PCB (printed circuit board), an FPC (flexible printed circuit,), or a COF (chip on film).

The second substrate 200 may include a plurality of second conductive pads 7. For example, the plurality of second conductive pads 7 may be arranged along the first direction X, that is, the plurality of second conductive pads 7 form a row of second conductive pads. For example, the plurality of second conductive pads 7 and the plurality of first conductive pads 3 may be in a one-to-one correspondence. That is, an arrangement period of the second conductive pads 7 is the same as an arrangement period of the first conductive pads 3.

For example, a bonding wire 9 electrically connects the first conductive pad 3 and the second conductive pad 7. One end of the bonding wire 9 is connected to the first conductive pad 3, and the other end of the bonding wire 9 is connected to the second conductive pad 7. That is, one end of the bonding wire 9 is soldered onto the first conductive pad 3, and the other end of the bonding wire 9 is soldered onto the second conductive pad 7. A solder joint on the first conductive pad 3 is referred to as a first solder joint 911, and a solder joint on the second conductive pad 7 is referred to as a second solder joint 921. For example, the bonding wire 9 may adopt a metal such as Cu, Al, Au and Ag, or may adopt an alloy thereof.

The second substrate 200 may further include an external driver circuit, such as, an integrated circuit chip, but the embodiments of the present disclosure are not limited thereto.

The display substrate 100 may be a backplane used for a light emitting diode display panel. The display substrate 100 includes, but is not limited to, the following backplanes: a passive drive backplane, an active drive backplane containing thin film transistors, or an active drive backplane driven by a micro IC.

A specific example will be used to illustrate the display substrate 100 below, however, the following specific example should not be considered as limiting the embodiments of the present disclosure. The backplane according to the embodiments of the present disclosure may include drive backplanes of various types and structures known in the art.

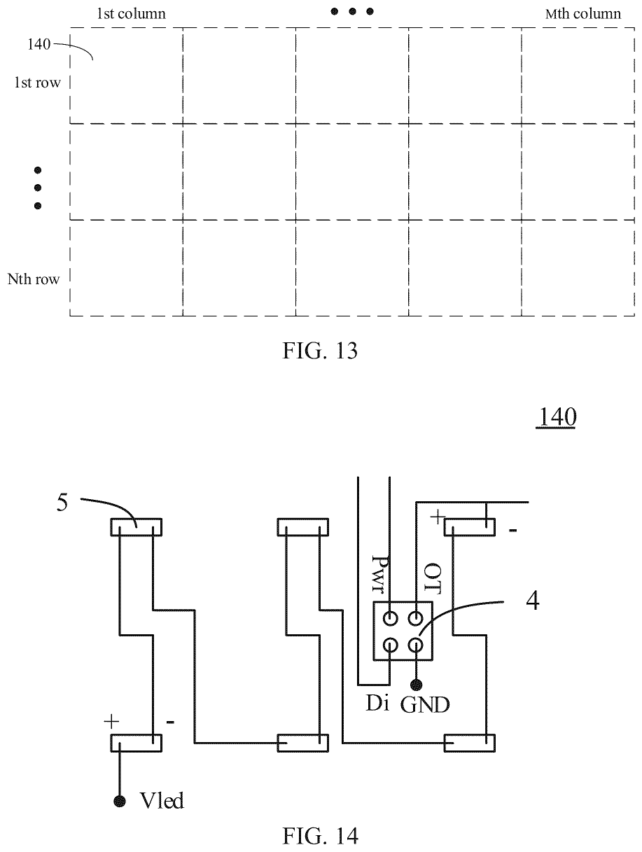

FIG. 13 shows a schematic diagram of an arrangement of light emitting units of the display substrate shown in FIG. 1, and FIG. 14 shows a schematic diagram of a light emitting unit in the display substrate shown in FIG. 13. As shown in FIG. 1, FIG. 13 and FIG. 14, the display substrate 100 may include a base substrate 1 and a plurality of light emitting units 140 arranged in an array on the base substrate 1. For example, the plurality of light emitting units 140 are arranged in N rows and M columns, where N is an integer larger than 0 and M is also an integer larger than 0. For example, the number of the light emitting units 140 may be determined as desired, for example, the number may be determined according to the size of the display substrate and the required brightness. Although only three rows and five columns of light emitting units 140 are shown in FIG. 13, it should be understood that the number of the light emitting units 140 is not limited thereto.

For example, each row of light emitting units 140 are arranged along the first direction X, and each column of light emitting units 140 are arranged along the second direction Y.

Each light emitting unit 140 includes the driver circuit 4, a plurality of light emitting diodes 5, and a driving voltage terminal Vled.

The driver circuit 4 includes a first input terminal Di, a second input terminal Pwr, an output terminal OT, and a common voltage terminal GND. The first input terminal Di receives a first input signal, and the first input signal may be, for example, an address signal used to enable a driver circuit 4 of a corresponding address. For example, addresses of different driver circuits 4 may be the same or different. The first input signal may be an 8 bit address signal, and an address to be transmitted may be acquired by analyzing the address signal. The second input terminal Pwr receives a second input signal, and the second input signal may be, for example, a power line carrier communication signal. For example, the second input signal not only provides power for the driver circuit 4, but also transmits communication data to the driver circuit 4. The communication data may be used to control a light emission duration of a corresponding light emitting unit 140, so as to control a visual perception brightness of the light emitting unit 140. The output terminal OT may respectively output different signals in different time periods. For example, the output terminal OT may respectively output a relay signal and a driving signal. For example, the relay signal is the address signal provided for another driver circuit 4, that is, the first input terminal Di of the other driver circuit 4 receives the relay signal as the first input signal, so that the address signal is acquired. For example, the driving signal may be a driving current for driving the light emitting diode 5 to emit light. The common voltage terminal GND receives a common voltage signal, such as a ground signal.

The driver circuit 4 is configured to output the relay signal through the output terminal OT in a first period based on the first input signal received by the first input terminal Di and the second input signal received by the second input terminal Pwr, and to provide the driving signal through the output terminal OT to the plurality of light emitting diode 5 that are sequentially connected in series in a second period. In the first period, the output terminal OT outputs the relay signal, and the relay signal is provided to another driver circuit 4, so that the other driver circuit 4 acquires the address signal. In the second period, the output terminal OT outputs the driving signal, and the driving signal is provided to the plurality of light emitting diode 5 that are sequentially connected in series, so that the light emitting diodes 5 emit light in the second period. For example, the first time period and the second time period are different time periods, and the first time period may be, for example, earlier than the second time period. The first time period and the second time period may be consecutive, that is, the end time instant of the first time period is a start time instant of the second time period. Alternatively, there may be another time period between the first time period and the second time period, and another time period may be used to achieve other required functions. The other time period may also be used to only separate the first time period from the second time period, so as to prevent the signals output by the output terminal OT in the first time period and the second time period from interfering with each other.

For example, as shown in FIG. 14, a plurality of light emitting diodes 5 are sequentially connected in series between the driving voltage terminal Vled and the output terminal OT. For example, each light emitting diode 5 includes a positive pole (+) and a negative pole (−) (alternatively, they may be referred to as an anode and a cathode, or they may also be referred to as a P electrode and an N electrode). The positive poles and the negative poles of the plurality of light emitting diodes 5 are sequentially connected end to end in series so as to form a current path between the driving voltage terminal Vled and the output terminal OT. The driving voltage terminal Vled provides a driving voltage, which is, for example, a high voltage in a period (the second period) when the light emitting diodes 5 are required to emit light, and a low voltage in other periods. In this way, in the second period, the driving signal (e.g., the driving current) flows from the driving voltage terminal Vled and then through the plurality of light emitting diodes 5 sequentially, and finally into the output terminal OT of the driver circuit 4. The plurality of light emitting diodes 5 emit light when the driving current flows through the plurality of light emitting diodes 5, and the light emitting period of the light emitting diodes 5 may be controlled by controlling a duration of the driving current, so as to control a visual perception brightness.

It should be noted that, in the embodiments of the present disclosure, the number of the light emitting diodes 5 in each light emitting unit 140 is not limited, and the light emitting unit 140 may include any number of light emitting diode 5, such as 4, 5, 7 and 8, and the number is not limited to 6. The plurality of light emitting diodes 5 may be arranged in any manner, for example, they may be arranged according to a required pattern, and are not limited to being arranged in a matrix. A position where the driver circuit 4 is provided is not limited, and the driver circuit 4 may be provided in any gap between the light emitting diodes 5, which may be determined as desired, and is not limited in the embodiments of the present disclosure.

For example, referring back to FIG. 1, the driver circuit 4 in each light emitting unit 140 may be led to the first conductive pad 3 in the fan-out region through a signal line 150, and then may be led to an external driver circuit through the bonding wire 9 and the second conductive pad 7.

In the embodiments of the present disclosure, the driver circuit 4 may include a metal layer, for example, a conductive wire may be formed in the metal layer. As the display substrate has a large current load, which may reach tens of milliamperes, there is a high requirement for the resistance of the wire. Copper is used as a main body of the conductive wire due to its good conductivity. Certainly, the material of the conductive wire is not limited to copper, other metals may also be used, such as silver and aluminum. As shown in FIG. 2, the conductive wire includes a copper layer 32, and a thickness of the copper layer 32 may be adjusted according to a magnitude of the current load. The larger the current load, the larger the thickness of the copper layer 32. The thickness of the copper layer 32 may be in a range of 1 micron to 30 microns, and in some embodiments, it may be specifically in a range of 2 microns to 6 microns, such as 2 microns, 4 microns, 5 microns and 6 microns. The copper layer 32 may be formed by electroplating.

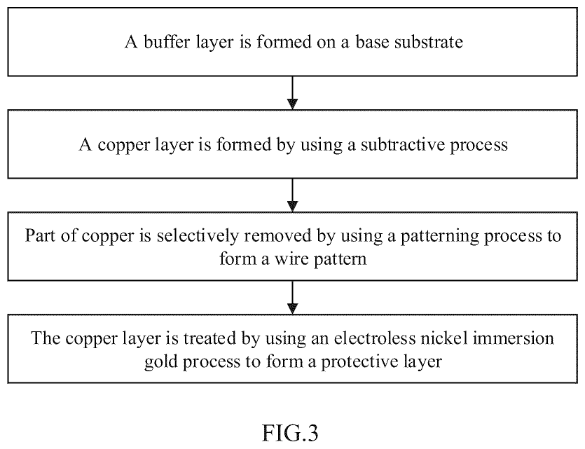

In the related technology, the copper layer 32 is usually formed by the subtractive process. FIG. 3 shows a flowchart of a method for forming a copper layer by using the subtractive process in a related technology. According to this method, a buffer layer is first formed on the base substrate, for example, the buffer layer may include one or more insulating materials of silicon nitride, silicon oxide, and silicon oxynitride, and may have a stress direction opposite to a stress direction of the formed copper layer, so that the stress generated during the formation of the copper layer may be counteracted and the base substrate may be prevented from being broken. Then, a copper layer is formed by using the subtractive process. The so-called subtractive process is a method of selectively removing part of copper foil on a surface of a copper clad laminate so as to obtain a conductive pattern. For example, a thick copper layer may be formed on the buffer layer, and then a patterning process is used to selectively remove part of copper so as to form a wire pattern. Subsequently, the copper layer is treated by using an electroless nickel immersion gold process to form a protective layer. The so-called electroless nickel immersion gold process refers to a solderable surface coating process in which nickel is first chemically plated on a bare copper surface and gold is then plated by chemical immersion.

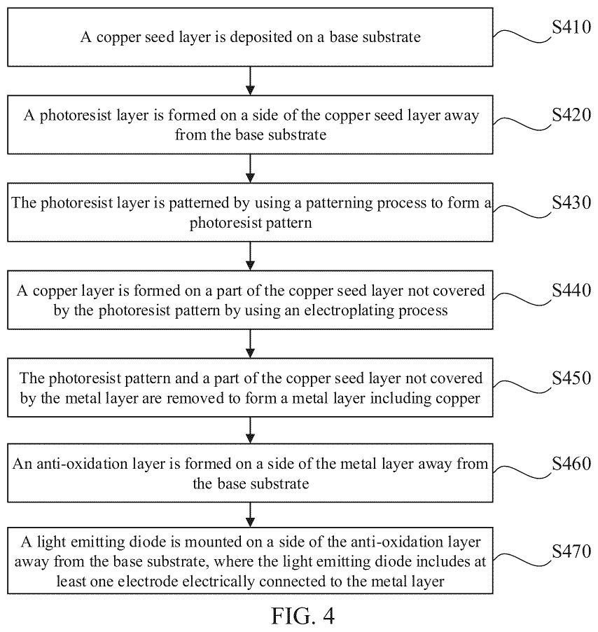

FIG. 4 shows a flowchart of a method for manufacturing a display substrate according to some exemplary embodiments of the present disclosure. According to the method, a metal layer may be formed by using an additive process, and the method may include steps S410 to S470. It should be noted that some steps of the manufacturing method described below may be performed individually or in combination, and may be performed in parallel or in sequence and are not limited to the specific operation sequence shown in the figure.

In step S410, a copper seed layer is deposited on a base substrate.

In step S420, a photoresist layer is formed on a side of the copper seed layer away from the base substrate.

In step S430, the photoresist layer is patterned by using a patterning process to form a photoresist pattern.

In step S440, a copper layer is formed on a part of the copper seed layer not covered by the photoresist pattern by using an electroplating process.

In step S450, the photoresist pattern and a part of the copper seed layer not covered by the metal layer are removed, so as to form a metal layer including copper.

In step S460, an anti-oxidation layer is formed on a side of the metal layer away from the base substrate.

In step S470, a light emitting diode is mounted on a side of the anti-oxidation layer away from the base substrate, where the light emitting diode includes at least one electrode electrically connected to the metal layer.

In the embodiments of the present disclosure, a first thickness of the metal layer is larger than a second thickness of the anti-oxidation layer. For example, the thickness of the metal layer may be in a range of 5 microns to 30 microns. In some embodiments, specifically, the thickness of the metal layer may be in a range of 5 microns to 10 microns, such as 5 microns, 6 microns, 7 microns and 8 microns.

According to the embodiments of the present disclosure, a metal layer with a large thickness may be formed on the LED display substrate by using the additive process, which may save the manufacturing costs.

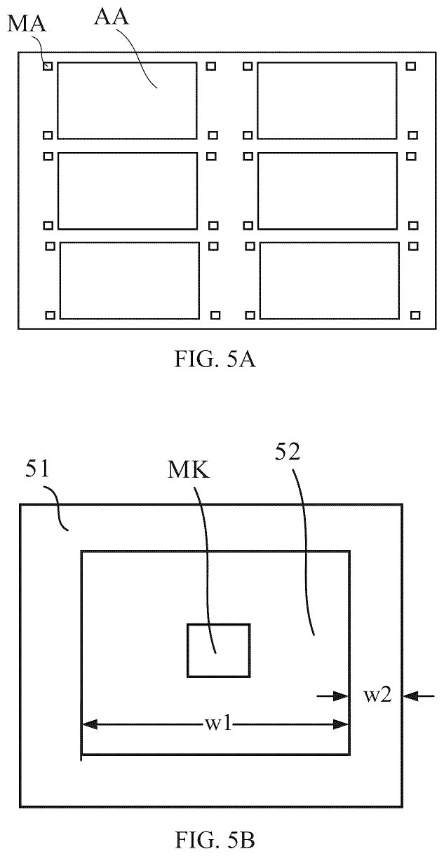

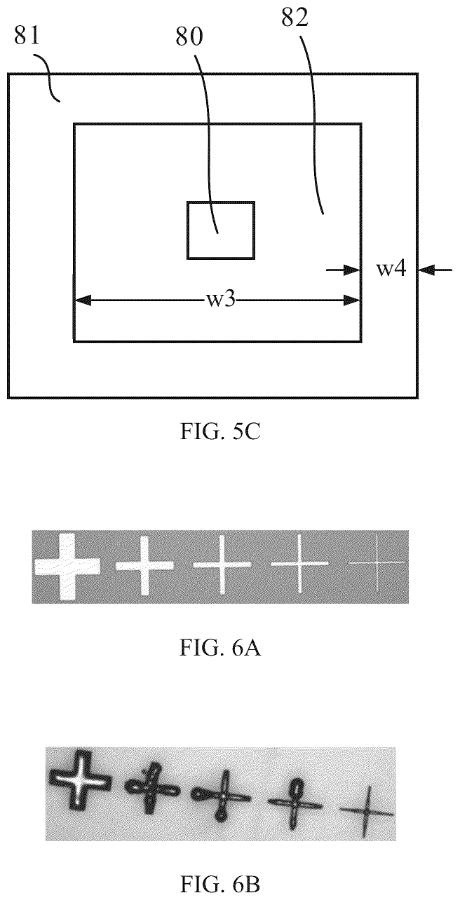

FIG. 5A shows a partial schematic top view of a display substrate according to some exemplary embodiments of the present disclosure, where a display region and a mark region are schematically shown. FIG. 5B shows a partially enlarged diagram of the marked region shown in FIG. 5A. FIG. 5C shows a partially enlarged diagram of the display region shown in FIG. 5A. FIG. 6A shows a schematic diagram of a mark formed by a method for manufacturing a display substrate according to some exemplary embodiments of the present disclosure. FIG. 6B shows a schematic diagram of a mark formed by a method for manufacturing a display substrate in a related technology.

Referring to FIG. 1 to FIG. 5C, the base substrate may include a display region AA and a mark region MA. For example, the display region AA may be a region for display, for example, the light emitting diodes described above may be within the display region AA. The mark region MA may be a region for formation of an alignment mark MK.

In step S440, the forming a copper layer on a part of the copper seed layer not covered by the photoresist pattern by using an electroplating process may include: forming a first accompanying plating region 51 in the mark region MA; and forming a second accompanying plating region 81 in the display region AA.

In the embodiments of the present disclosure, the first accompanying plating region 51 and the second accompanying plating region 81 each include a part of the copper layer. A ratio of an arca of the first accompanying plating region 51 to an area of the mark region MA is larger than a ratio of an area of the second accompanying plating region 81 to an area of the display region AA. According to the embodiments of the present disclosure, a good electroplating uniformity may be achieved by providing different accompanying plating regions for the display region and the mark region.

The ratio of the area of the first accompanying plating area 51 to the area of the mark region MA indicates a copper proportion in the mark region MA, and the ratio of the area of the second accompanying plating area 81 to the area of the display region AA indicates a copper proportion in the display region AA. According to the embodiments of the present disclosure, the copper proportion in the mark region MA is larger than the copper proportion in the display region AA.

In the exemplary embodiments shown in FIG. 5B and FIG. 5C, the areas of the first accompanying plating region 51 and the second accompanying plating region 81 may be characterized by areas of loop-shaped region. A region surrounded by an outer contour of the first accompanying plating region 51 is in a shape of a square, a region surrounded by an outer contour of a clearance region 52 is in a shape of a square, a region surrounded by an outer contour of the second accompanying plating area 81 is in a shape of a square, and a region surrounded by an outer contour of a clearance region 82 is in a shape of a square.

Correspondingly, the copper proportion M1 in the mark region MA may be represented by a formula.

The copper proportion M2 in the display region AA may be represented by the a formula.

It should be understood by those skilled in the art that in the electroplating process, in a case that no accompanying plating region is provided, the electric field lines being dense may lead to a large electroplating rate. As a result, when the metal layer is formed, the thickness of the metal may exceed the thickness of the photoresist pattern, resulting in deformation of the formed part.

It may be seen from FIG. 6B that in the case that no accompanying plating region is provided in the mark region, deformation occurs to the formed mark, thereby affecting the alignment accuracy. It can be seen from FIG. 6A that in the case that the accompanying plating region is provided in the mark region, the formed mark is more accurate, which may be beneficial to the improvement of the alignment accuracy.

Referring to FIG. 5B and FIG. 6A, the method may further include: forming a mark MK by using an electroplating process in the region surrounded by the first accompanying plating region 51.

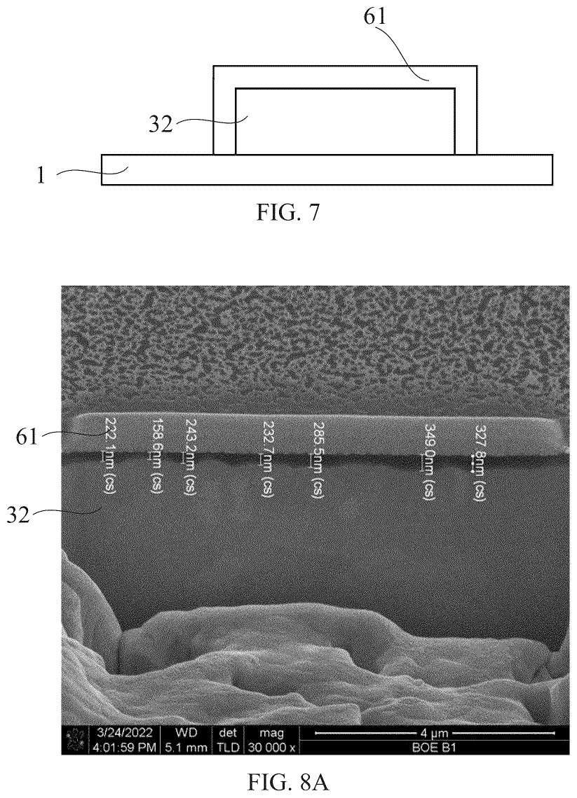

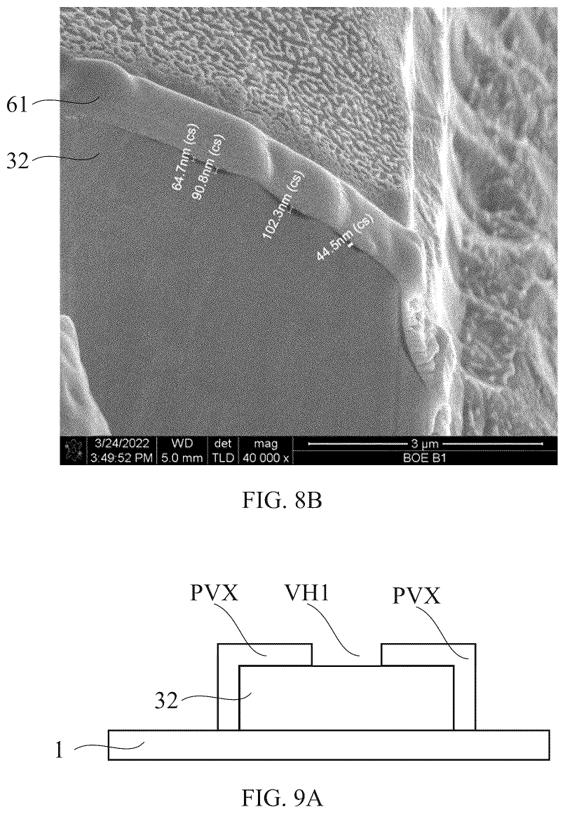

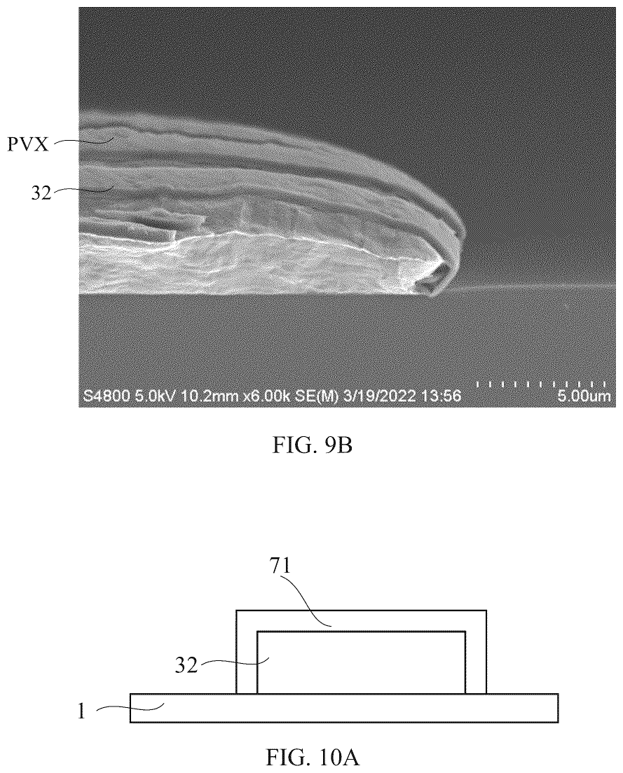

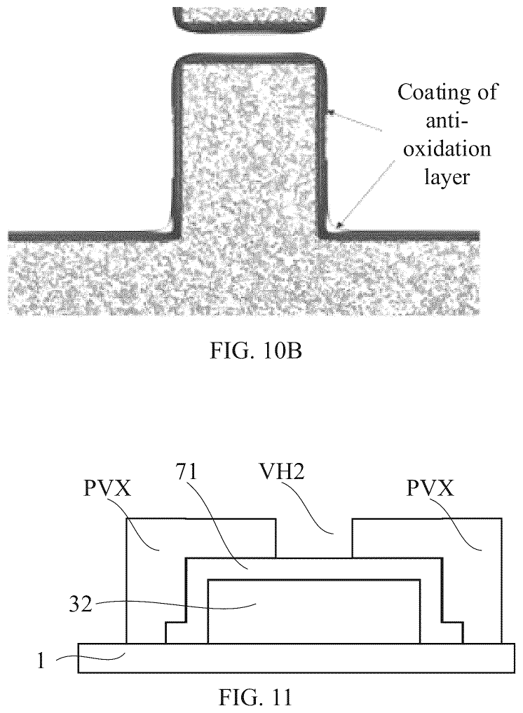

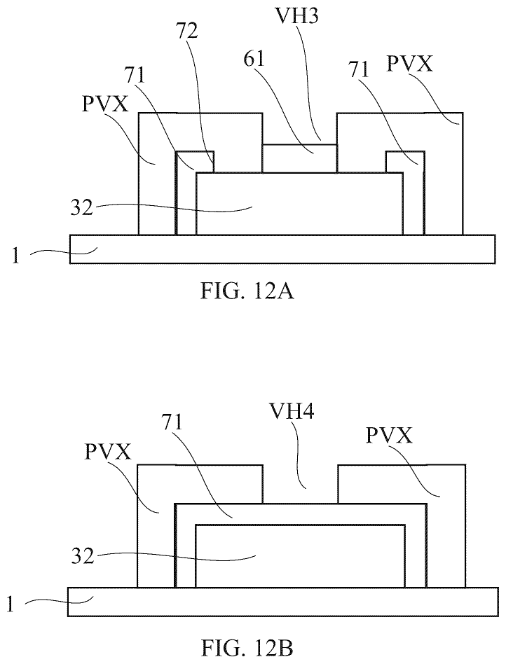

FIG. 7 shows a partial sectional view of a display substrate according to some exemplary embodiments of the present disclosure, where a positional relationship between a metal layer and an anti-oxidation layer is schematically shown. FIG. 8A and FIG. 8B respectively show electron microscope images of regions I and II in FIG. 7. FIG. 9A shows a partial sectional view of a display substrate according to some other exemplary embodiments of the present disclosure, where a positional relationship between a metal layer and an anti-oxidation layer is schematically shown. FIG. 9B is an electron microscopic image of region III in FIG. 9A. FIG. 10A and FIG. 10B respectively show a partial sectional view and a partial top view of a display substrate according to yet some other exemplary embodiments of the present disclosure, where a positional relationship between a metal layer and an anti-oxidation layer is schematically shown. FIG. 11 shows a partial sectional view of a display substrate according to some other exemplary embodiments of the present disclosure, where a positional relationship between a metal layer and an anti-oxidation layer is schematically shown. FIG. 12A and FIG. 12B respectively show partial sectional views of a display substrate at a first position and a second position according to some other exemplary embodiments of the present disclosure, where a positional relationship between a metal layer and an anti-oxidation layer is schematically shown.

Referring to FIG. 7, in step S460, the forming an anti-oxidation layer on a side of the metal layer away from the base substrate may include: forming an OSP layer 61 on a side of the metal layer 32 away from the base substrate.

For example, the metal layer 32 may be a copper layer with a large thickness. After the copper layer with the large thickness is formed, acid pickling is performed on a surface of the copper layer, so that the surface of the copper layer 32 has a micro-etching depth of 1 micron to 2 microns. An OSP immersion process is then performed, and the OSP reacts with the surface of the copper layer. In this way, an outer surface of the copper layer 32 is coated with a layer of OSP. For example, a middle part of the OSP layer 61 has a thickness in a range of 0.2 microns to 0.4 microns, as shown in FIG. 8A. As shown in FIG. 8B, the OSP layer is relatively thin at the slope portion of the edge after the OSP process, and a thickness thereof ranges from 0 to 0.1 microns.

Referring to FIG. 9A, in step S460, the forming an anti-oxidation layer on a side of the metal layer away from the base substrate may include: forming a passivation layer PVX on the side of the metal layer 32 away from the base substrate; forming a first via hole VH1 in the passivation layer, where the first via hole exposes at least a part of the metal layer; and forming the anti-oxidation layer in the first via hole VH1. For example, the anti-oxidation layer includes an organic solderability preservative film, that is, the anti-oxidation layer is the OSP layer 61.

For example, the metal layer 32 may be the copper layer with the large thickness. After the copper layer 32 with the large thickness is formed, the passivation layer is coated on an outer surface of the copper layer 32, so as to achieve good coating property and reliability, and meet high temperature and high humidity requirements. A position where the first via hole VH1 is formed may be a pad position and a bonding position. Then, acid pickling is performed on the surface, so that an exposed surface of the copper layer 32 has a micro-etching depth of 1 micron to 2 microns. An OSP immersion process is then performed, and the OSP reacts with the surface of the copper layer. In this way, the exposed outer surface of the copper layer 32 is coated with a layer of OSP.

According to this embodiment, the outer surface of the metal layer is first coated with the passivation layer, so that the OSP film layer at the slope portion of the edge may be prevented from being thin after the OSP process, which is conducive to the uniform coating of the metal layer. As shown in FIG. 9B, a middle part of the passivation layer PVX has a thickness substantially equal to a thickness of the edge. That is, the passivation layer PVX may improve the coating uniformity of the metal layer, so that a protection effect may be improved.

Referring to FIG. 10A, in step S460, the forming an anti-oxidation layer on a side of the metal layer away from the base substrate may include: forming a nickel-containing alloy layer 71 covering the metal layer on a side of the metal layer 32 away from the base substrate.

The nickel-containing alloy layer 71 has oxidation resistance and good soldering performance. For example, the nickel-containing alloy layer 71 may be CuNi, where a mass percent of Ni is 10% to 30%; or, the nickel-containing alloy layer 71 may be NiV, where a mass percent of Ni is 50% to 97%; or, the nickel-containing alloy layer 71 may be NiW, where a mass percentage of Ni is 50% to 97%.

For example, a thickness of the nickel-containing alloy layer 71 may be in a range of 500 angstroms to 4000 angstroms. A pattern of the nickel-containing alloy layer 71 may be formed by photolithography.

Referring to FIG. 11, in step S460, the forming an anti-oxidation layer on a side of the metal layer away from the base substrate includes: forming a nickel-containing alloy layer 71 covering the metal layer on the side of the metal layer 32 away from the base substrate; forming the passivation layer PVX on a side of the nickel-containing alloy layer 71 away from the base substrate; and forming a second via hole VH2 in the passivation layer PVX, where the second via hole VH2 exposes at least a part of the nickel-containing alloy layer 71.

For example, the metal layer 32 may be the copper layer with the large thickness. After the copper layer 32 with large thickness is formed, the nickel-containing alloy layer 71 is coated on an outer surface of the copper layer 32, so as to achieve good coating property and reliability and meet high temperature and high humidity requirements. A position where the second via hole VH2 is formed may be a pad position and a bonding position.

Referring to FIG. 12A and FIG. 12B, in step S460, the forming an anti-oxidation layer on a side of the metal layer away from the base substrate includes: forming a nickel-containing alloy layer 71 covering the metal layer on the side of the metal layer 32 away from the base substrate; forming an opening 72 in the nickel-containing alloy layer at a pad position of the display region AA, where the opening 72 exposes at least a part of the metal layer 32; forming the passivation layer PVX on the side of the nickel-containing alloy layer 71 away from the base substrate; and forming a third via hole VH3 in the passivation layer PVX at the pad position of the display region, where the third via hole VH3 exposes at least a part of the metal layer 32.

In this embodiment, an orthographic projection of the third via hole VH3 on the base substrate is within an orthographic projection of the opening 72 on the base substrate.

In step S460, the forming an anti-oxidation layer on a side of the metal layer away from the base substrate further includes: forming a fourth via hole VH4 in the passivation layer PVX at a bonding position, where the fourth via hole VH4 exposes at least a part of the nickel-containing alloy layer 71.

In this embodiment, as the compound used in the OSP process only reacts with copper to achieve the OSP layer without reacting with the nickel-containing alloy layer 71, the pad region in the display region AA may be well protected. No organic protective layer is formed in the bonding region, which prevents a poor contact between the bonding region and an external circuit, or prevents an increase of contact resistance.

According to the embodiments of the present disclosure, a nickel-containing alloy and/or an OSP is used as the anti-oxidation layer to solve the anti-oxidation problem of copper with the large thickness, and a process route having a good effect and low costs is obtained. With the protection of the nickel-containing alloy and/or the OSP, the electroless nickel immersion gold process is avoided, so that the manufacturing costs of the display substrate are greatly saved.

On the basis of the above manufacturing method provided in the embodiments of the present disclosure, according to some exemplary embodiments of the present disclosure, there is further provided a display substrate. Referring to FIG. 1, FIG. 2, and FIG. 9A to FIG. 12B, the display substrate includes: a base substrate 1; a metal layer on the base substrate, where the metal layer includes a copper layer 32 having a first thickness; an anti-oxidation layer 61, 71 on a side of the metal layer 32 away from the base substrate, where the anti-oxidation layer having a second thickness; and a light emitting diode 5 on a side of the anti-oxidation layer away from the base substrate, where the light emitting diode 5 includes at least one electrode electrically connected to the metal layer. The first thickness of the metal layer 32 is larger than the second thickness of the anti-oxidation layer 61/71.

Referring to FIG. 5A and FIG. 5B, the base substrate 1 includes a display region AA and a mark region MA, and the display substrate includes a first accompanying plating region 51 in the mark region MA and a second accompanying plating region in the display region AA. Each of the first accompanying plating region 51 and the second accompanying plating region includes a copper layer. A ratio of an area of the first accompanying plating region 51 to an area of the mark region MA is larger than a ratio of an area of the second accompanying plating region to an area of the display region AA.

Specifically, the display substrate further includes a mark MK in the mark region and a clearance region 52 in the mark region. The first accompanying plating region 51 surrounds the mark MK, and the clearance region 52 is between the mark MK and the first accompanying plating region 51 and surrounds the mark.

It should be noted that the clearance region refers to a region reserved only for a pattern required for alignment under an alignment lens so as to prevent other patterns from affecting the alignment during an alignment process by an exposure machine, and this region only keeps the pattern for alignment.

For example, as shown in FIG. 5B, an orthographic projection of the first accompanying plating region 51 on the base substrate 1 is a loop-shaped region surrounding the mark MK.

As shown in FIG. 10A, the anti-oxidation layer 71 covers the metal layer 32, and the at least one electrode of the light emitting diode is electrically connected to the metal layer through the anti-oxidation layer.

As shown in FIG. 11, the display substrate further includes a passivation layer PVX on the anti-oxidation layer 71 away from the base substrate 1, and a first via hole VH1 in the passivation layer. The first via hole VH1 exposes at least a part of the anti-oxidation layer 71, and the at least one electrode of the light emitting diode is electrically connected to the metal layer 32 through the first via hole VH1.

For example, the anti-oxidation layer 71 covers the metal layer 32.

As shown in FIG. 12A, the display substrate further includes a passivation layer PVX on the anti-oxidation layer 71 away from the base substrate, and a third via hole VH3 in the passivation layer. The third via hole VH3 is at a pad position of the display region, the third via hole VH3 exposes at least a part of the metal layer 32, and the at least one electrode of the light emitting diode is electrically connected to the metal layer through the third via hole.

The anti-oxidation layer includes an opening 72. The opening 72 exposes at least a part of the metal layer 32, and an orthographic projection of the third via hole VH3 on the base substrate is within an orthographic projection of the opening 72 on the base substrate.

As shown in FIG. 12B, the display substrate further includes a fourth via hole VH4 in the passivation layer PVX. The fourth via hole VH4 is at a bonding position, the fourth via hole VH4 exposes at least a part of the anti-oxidation layer 71, and the at least one electrode of the light emitting diode is electrically connected to the metal layer through the exposed part of the anti-oxidation layer.

It should be noted that, in the embodiments of the present disclosure, the thickness of the copper layer 32 is larger than the thickness of the passivation layer PVX, the thickness of the passivation layer PVX is larger than the respective thicknesses of the OSP layer 61 and the anti-oxidation layer 71, and the thickness of the OSP layer 61 and the thickness of the anti-oxidation layer 71 are substantially equal. For example, the copper layer 32 has a large thickness which is, for example, in a range of 5 microns to 10 microns. The thickness of the passivation layer PVX may be in a range of 3000 angstroms to 5000 angstroms. When the thickness of the passivation layer PVX is larger than 5000 angstroms, the passivation layer PVX may has a large stress. When the thickness of the passivation layer PVX is less than 2000 angstroms, the coating performance of the passivation layer PVX on a side surface of the copper layer 32 may be affected. The thicknesses of the OSP layer 61 are substantially equal to the thickness of the anti-oxidation layer 71, which may be in a range of 2000 angstroms to 4000 angstroms.

According to some exemplary embodiments of the present disclosure, there is further provided a display device. FIG. 11 and FIG. 12 show schematic diagrams of a display device according to some exemplary embodiments of the present disclosure. Referring to FIG. 11 and FIG. 12, the display device includes at least two display substrates as described above.

It should be understood that the display device according to some exemplary embodiments of the present disclosure has all the characteristics and advantages of the display substrate described. For these characteristics and advantages, reference may be made to the description of the display substrate above, and details will not be repeated here.

As used herein, the terms “substantially”, “about”, “approximately” and other similar terms are used as terms of approximation rather than of degree, and they are intended to explain an inherent deviation of a measured value or a calculated value that would be recognized by those of ordinary skill in the art. Considering factors, such as process fluctuations, measurement problems, and errors associated with measurement of a specific amount (i.e., limitation of a measurement system), the expression “about” or “approximately” as used herein includes the stated value and means that a specific value determined by those of ordinary skill in the art is within an acceptable deviation range. For example, the expression “about” may refer to being within one or more standard deviations, or within +10% or +5% of the stated value.

Although some embodiments according to the general inventive concept of the present disclosure have been illustrated and described, those of ordinary skill in the art will understand that, without departing from the principles and spirits of the general inventive concept of the present disclosure, modifications may be made to these embodiments. The scope of the present disclosure is defined by the claims and the equivalents thereof.

1. A display substrate, comprising:
a base substrate;
a metal layer on the base substrate, comprising a copper layer having a first thickness;
an anti-oxidation layer on a side of the metal layer away from the base substrate, having a second thickness; and
a light emitting diode on a side of the anti-oxidation layer away from the base substrate, comprising at least one electrode, wherein the at least one electrode of the light emitting diode is electrically connected to the metal layer,
wherein the first thickness of the metal layer is larger than the second thickness of the anti-oxidation layer.

2. The display substrate of claim 1, wherein the anti-oxidation layer comprises a nickel-containing alloy.

3. The display substrate of claim 1, wherein the base substrate comprises a display region and a mark region, and the display substrate comprises a first accompanying plating region in the mark region and a second accompanying plating region in the display region,
wherein each of the first accompanying plating region and the second accompanying plating region comprises a copper layer; and
wherein a ratio of an area of the first accompanying plating region to an area of the mark region is larger than a ratio of an area of the second accompanying plating region to an area of the display region.

4. The display substrate of claim 3, wherein the display substrate further comprises a mark in the mark region and a clearance region in the mark region, and
the first accompanying plating region surrounds the mark, and the clearance region is between the mark and the first accompanying plating region and surrounds the mark.

5. The display substrate of claim 4, wherein an orthographic projection of the first accompanying plating region on the base substrate is a loop-shaped region surrounding the mark.

6. The display substrate of claim 1, wherein the anti-oxidation layer covers the metal layer, and the at least one electrode of the light emitting diode is electrically connected to the metal layer through the anti-oxidation layer.

7. The display substrate of claim 1, wherein the display substrate further comprises a passivation layer on the anti-oxidation layer away from the base substrate and a first via hole in the passivation layer,
wherein the first via hole exposing at least a part of the anti-oxidation layer, and the at least one electrode of the light emitting diode is electrically connected to the metal layer through the first via hole.

8. The display substrate of claim 1, wherein the anti-oxidation layer covers the metal layer.

9. The display substrate of claim 1, wherein the display substrate further comprises a passivation layer on the anti-oxidation layer away from the base substrate and a third via hole in the passivation layer,
wherein the third via hole is located at a pad position of the display region and exposes at least a part of the metal layer, and the at least one electrode of the light emitting diode is electrically connected to the metal layer through the third via hole.

10. The display substrate of claim 9, wherein the display substrate further comprises a fourth via hole in the passivation layer,
wherein the fourth via hole is located at a bonding position and exposes at least a part of the anti-oxidation layer, and the at least one electrode of the light emitting diode is electrically connected to the metal layer through the exposed part of the anti-oxidation layer.

11. The display substrate of claim 9, wherein the anti-oxidation layer comprises an opening exposing at least a part of the metal layer, and an orthographic projection of the third via hole on the base substrate is within an orthographic projection of the opening on the base substrate.

12. A method for manufacturing a display substrate, comprising:
depositing a copper seed layer on a base substrate;
forming a photoresist layer on a side of the copper seed layer away from the base substrate;
patterning the photoresist layer by using a patterning process to form a photoresist pattern;
forming a copper layer on a part of the copper seed layer not covered by the photoresist pattern by using an electroplating process;
removing the photoresist pattern and a part of the copper seed layer not covered by the metal layer to form a metal layer comprising copper;
forming an anti-oxidation layer on a side of the metal layer away from the base substrate; and
mounting a light emitting diode on a side of the anti-oxidation layer away from the base substrate, wherein the light emitting diode comprises at least one electrode electrically connected to the metal layer,
wherein a first thickness of the metal layer is larger than a second thickness of the anti-oxidation layer.

13. The method of claim 12, wherein the base substrate comprises a display region and a mark region, and the forming a copper layer on a part of the copper seed layer not covered by the photoresist pattern by using an electroplating process comprises:
forming a first accompanying plating region in the mark region; and
forming a second accompanying plating region in the display region,
wherein each of the first accompanying plating region and the second accompanying plating region comprises a part of the copper layer; and
wherein a ratio of an area of the first accompanying plating region to an area of the mark region is larger than a ratio of an area of the second accompanying plating region to an area of the display region.

14. The method of claim 13, wherein the method further comprises forming a mark by using an electroplating process in a region surrounded by the first accompanying plating region.

15. The method of claim 12, wherein the forming an anti-oxidation layer on a side of the metal layer away from the base substrate comprises:
forming a passivation layer on the side of the metal layer away from the base substrate;
forming a first via hole in the passivation layer, wherein the first via exposes at least a part of the metal layer; and
forming the anti-oxidation layer in the first via hole,
wherein the anti-oxidation layer comprises an organic solderability preservative film.

16. The method of claim 12, wherein the forming an anti-oxidation layer on a side of the metal layer away from the base substrate comprises:
forming a nickel-containing alloy layer covering the metal layer on the side of the metal layer away from the base substrate.

17. The method of claim 12, wherein the forming an anti-oxidation layer on a side of the metal layer away from the base substrate comprises:
forming a nickel-containing alloy layer covering the metal layer on the side of the metal layer away from the base substrate;
forming a passivation layer on a side of the nickel-containing alloy layer away from the base substrate; and
forming a second via hole in the passivation layer, wherein the second via hole exposes at least a part of the nickel-containing alloy layer.

18. The method of claim 12, wherein the forming an anti-oxidation layer on a side of the metal layer away from the base substrate comprises:
forming a nickel-containing alloy layer covering the metal layer on the side of the metal layer away from the base substrate;
forming an opening in the nickel-containing alloy layer at a pad position of the display region, wherein the opening exposes at least a part of the metal layer;
forming a passivation layer on a side of the nickel-containing alloy layer away from the base substrate; and
forming a third via hole in the passivation layer at the pad position of the display region, wherein the third via hole exposes at least a part of the metal layer,
wherein an orthographic projection of the third via hole on the base substrate is located within an orthographic projection of the opening on the base substrate.

19. The method of claim 18, wherein the forming an anti-oxidation layer on a side of the metal layer away from the base substrate further comprises:
forming a fourth via hole in the passivation layer at a bonding position, wherein the fourth via hole exposes at least a part of the nickel-containing alloy layer.

20. A display device, comprising the display substrate according to claim 1.
